(19) United States
(12) Patent Application Publication
(10) Pub. No.: US 2008/0157101 A1
(43) Pub. Date: Jul. 3, 2008

(54) TRANSISTOR ARRAY SUBSTRATE AND METHOD OF MANUFACTURING THE SAME

(75) Inventors: Tae-Hyung HWANG, Seoul (KR); Seong-Sik SHIN, Seongnam-si (KR); Nam-Seok ROH, Seongnam-si (KR); Sang-Il KIM, Yongin-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 11/955,528

(22) Filed: Dec. 13, 2007

(30) Foreign Application Priority Data
Dec. 28, 2006 (KR) 1020060136500

(51) Int. Cl. H01L 33/00

(52) U.S. Cl. 257/88; 438/34; 257/E33.053

(57) ABSTRACT

A transistor array substrate includes a first substrate including a pixel region and a transistor region. The pixel region includes a pixel electrode, a portion of a disconnected gate line and a portion of a disconnected data line. The transistor region includes first and second gate connecting portions respectively connected to disconnected portions of the gate line, and first and second data connecting portions respectively connected to disconnected portions of the data line. The transistor array substrate also includes a second substrate including a gate line connecting portion connected to the first and second gate connecting portions, a data line connecting portion connecting the first and second data connecting portions, and a transistor connected to the gate line connecting portion, the data line connecting portion and the pixel electrode. The second substrate is attached to the transistor region of the first substrate.

This application claims priority to and the benefit of Korean Patent Application No. 2006-0136500, filed Dec. 28, 2006, and all the benefits accruing therefrom under 35 U.S.C. §119, the contents of which in its entirety are herein incorporated by reference.

### BACKGROUND OF THE INVENTION

1. Field of the Invention

The present invention relates to a transistor array substrate and a method of manufacturing the same, and more particularly, to a transistor array substrate for a liquid crystal display (“LCD”) device and a method of manufacturing the same.

2. Description of the Related Art

In an information-oriented society, the importance of an LCD device as an information display means has been gradually increased. A cathode ray tube (“CRT”), which has been widely used has many advantages in performance, but is disadvantageous since it is relatively large in size and inconvenient to carry. To the contrary, an LCD device has advantages of being small in size, light in weight, thin in thickness, and low in power consumption, and thus its application has been increased.

Such an LCD device displays desired images such that an electric field is applied to a liquid crystal layer having anisotropic dielectric constant injected between two substrates, and an intensity of the electric field is adjusted to control an amount of transmitted light. The LCD device includes an LCD panel for displaying images, a driving portion for driving the LCD panel, and a backlight assembly for supplying light to the LCD panel. The LCD panel includes a color filter substrate in which a color filter array is formed, a thin film transistor (“TFT”) array substrate in which a TFT array is formed, and a liquid crystal layer interposed between the both substrates attached.

An LCD device has been developed, pursuing a relatively large-scaled screen, a high resolution, a fast display speed, and low power consumption in order to satisfy users' demand. In order to manufacture a large-scaled TFT array substrate, a large mask is necessary.

### BRIEF SUMMARY OF THE INVENTION

Since a manufacturing of a relatively large-scaled, high resolution, LCD device having a fast display speed and low power consumption requires a large mask, there are increased manufacturing costs. Additionally, since a plastic substrate is expanded by a heat applied when a TFT array is formed on the plastic substrate, such as during manufacturing, it is difficult to adjust an arrangement between layers.

An exemplary embodiment provides a transistor array substrate and a method of manufacturing the same, in which a structure of a transistor as a switching element used in an LCD device is simplified, whereby manufacturing costs for a mask and a TFT array substrate are lowered and a characteristic of a transistor as a switching element is improved.

In exemplary embodiments, a transistor array substrate includes a first substrate including a pixel region and a transistor region. The pixel region includes a pixel electrode, a portion of a disconnected gate line, and portion of a disconnected data line. The transistor region includes first and second gate connecting portions respectively connected to disconnected portions of the gate line, and first and second data connecting portions respectively connected to disconnected portions of the data line. The transistor array substrate also includes a second substrate including a gate line connecting portion connected to the first and second gate connecting portions of the first substrate, a data line connecting portion connecting the first and second data connecting portions of the first substrate, and a transistor connected to the gate line connecting portion and the data line connecting portion of the second substrate, and the pixel electrode of the first substrate. The second substrate is attached to the transistor region of the first substrate.

In an exemplary embodiment, the first substrate further may includes a passivation film insulating the pixel electrode from the gate line and the data line, and a first drain electrode disposed overlapping the transistor region, penetrating the passivation film and being connected to the pixel electrode.

In an exemplary embodiment, the gate line, the data line and the first drain electrode may be disposed on the same layer.

In an exemplary embodiment, the second substrate may include a crystalline silicon substrate.

In an exemplary embodiment, the transistor may include a drain including an ion is doped into the silicon substrate, a source including the ion is doped into the silicon substrate and connected to the data line connecting portion, a channel area disposed between the drain and the source, a gate oxide layer disposed covering the channel area, the source and the drain, and a gate electrode disposed on a portion of the gate oxide layer corresponding to the channel area, the gate electrode being connected to the gate connecting portion.

In an exemplary embodiment, the gate oxide layer includes first and second contact holes exposing portions of the drain and the source. The second substrate may further include a second drain electrode disposed on the gate oxide layer and connected to the drain through the first contact hole, and a source electrode disposed on the gate oxide layer and connected to the source through the second contact hole.

In an exemplary embodiment, the data connecting portion may be formed integrally with the source.

In an exemplary embodiment, the first substrate may further include a first leveling dummy disposed in the transistor region, and the second substrate further includes a second leveling dummy disposed corresponding to the first leveling dummy.

An exemplary embodiment provides a method of manufacturing a transistor array substrate. The method includes manufacturing step of manufacturing a first substrate, the first substrate including a pixel electrode, a portion of a disconnected gate line and a portion of a disconnected data line, manufacturing a second substrate, the second substrate including a gate line connecting portion, a data line connecting portion and a transistor, and attaching the second substrate to the first substrate such that the gate line connecting portion connects the portions of the disconnected gate line, the data line connecting portion connects the portions of the disconnected data line, and the transistor is connected to the pixel electrode.

In an exemplary embodiment, the manufacturing of a first substrate may include forming the pixel electrode on a glass substrate, forming a passivation film covering the pixel electrode, forming a contact hole on the passivation film and exposing a portion of the pixel electrode, and forming a first pattern on the passivation film, the first pattern including the gate line, the data line and the first drain electrode connected to the pixel electrode through the contact hole.

In an exemplary embodiment, the manufacturing a second substrate may include doping an ion into a crystalline silicon substrate and forming a source, a drain and a data line connecting portion formed integrally with the source, forming an insulating layer on the silicon substrate, removing the insulating layer and forming first, second and third contact holes exposing portions of the source, the drain and the data line connecting portion, respectively, and forming a second pattern on the insulating layer, the second pattern including a second drain electrode connected to the drain through the first contact hole, a source electrode connected to the source through the second contact hole, a gate electrode formed integrally with the gate connecting portion, and a connecting portion connected to the drain line connecting portion through the third contact hole.

In an exemplary embodiment, the second drain electrode, the source electrode and the gate electrode may be simultaneously formed.

In an exemplary embodiment, the step forming a first pattern may include forming first and second gate connecting portions connected to the portions of the disconnected gate line, and forming first and second data connecting portions connected to the portions of the disconnected data line.

In an exemplary embodiment, the forming the first, second and third contact holes may include forming the first and second contact holes exposing portions of the source and the drain, and forming the third contact hole exposing a portion of the data connecting portion.

In an exemplary embodiment, the attaching may include connecting the second drain electrode to the first drain electrode, connecting the gate connecting portion to the first and second gate connecting portions, connecting the source electrode to the first data connecting portion and connecting the connecting portion to the second connecting portion.

In an exemplary embodiment, the forming a first pattern may further include forming a first leveling dummy on the first substrate adjusting a height when the first and second substrates are attached, and the forming a second pattern further includes forming a second leveling dummy in the second substrate corresponding to the first leveling dummy.

An exemplary embodiment provides, a transistor array substrate including a first substrate including a pixel electrode, a disconnected gate line and a disconnected data line, and a second substrate including a gate line connecting portion connecting the disconnected gate line, a data line connecting portion connecting the disconnected data line, and a transistor connected to the gate line connecting portion, the data line connecting portion and the pixel electrode. The second substrate is attached to the first substrate.

In an exemplary embodiment, the second substrate may include a crystalline silicon substrate.

In an exemplary embodiment, the transistor may include a drain and a source including an ion doped into the crystalline silicon substrate, and a gate electrode insulated from a channel area disposed between the source and the drain.

In an exemplary embodiment, the drain may be connected to the pixel electrode, the source may be connected to the data line connecting portion, and the gate electrode may be connected to the gate line connecting portion.

In an exemplary embodiment, the data line connecting portion may be disposed on the same layer as the drain and the source, and the gate line connecting portion is disposed on the same layer as the gate electrode.

In an exemplary embodiment, the first substrate may further include an insulating layer insulating the pixel electrode from the gate line and the data line.

In an exemplary embodiment, the gate line and the data line may be disposed on the same layer.

### BRIEF DESCRIPTION OF THE DRAWINGS

The above and other features of the present invention will be described in reference to certain exemplary embodiments thereof with reference to the attached drawings in which:

FIG. 1 is a plan view illustrating an exemplary embodiment of a first substrate of a transistor array substrate according to the present invention;

FIG. 2 is a plan view illustrating an exemplary embodiment of a second substrate of the transistor array substrate according to the present invention;

FIGS. 3A and 3B are plan views illustrating an exemplary embodiment of the transistor array substrate in which the first substrate of FIG. 1 is coupled with the second substrate of FIG. 2;

FIGS. 4A and 4B are cross-sectional views illustrating the transistor array substrate taken along lines I-I′ and II-II′ of FIG. 3A, respectively;

FIG. 5 is a plan view illustrating an exemplary embodiment of a method of preparing a base substrate in manufacturing the second substrate of the transistor array substrate, according to the present invention;

FIGS. 6A and 6B are cross-sectional views taken along lines III-III′ and IV-IV′ of FIG. 5, respectively;

FIG. 7 is a plan view illustrating an exemplary embodiment of a first mask process in manufacturing the second substrate of the transistor array substrate, according to the present invention;

FIGS. 8A and 8B and FIGS. 9A and 9B are cross-sectional views taken along lines V-V′ and VI-VI′ of FIG. 7, respectively;

FIG. 10 is a plan view illustrating an exemplary embodiment of a second mask process in manufacturing the second substrate of the transistor array substrate according to the present invention;

FIGS. 11A and 11B are cross-sectional views taken along lines VII-VII′ and VIII-VIII′ of FIG. 10;

FIG. 12 is a plan view illustrating an exemplary embodiment of a third mask process in manufacturing the second substrate of the transistor array substrate, according to the present invention;

FIGS. 13A and 13B are cross-sectional views taken along lines IX-IX′ and X-X′ of FIG. 12;

FIG. 14 is a plan view illustrating an exemplary embodiment a first mask process in manufacturing the first substrate of the transistor array substrate, according to the present invention;

FIG. 15 is a cross-sectional view taken along line XI-XI′ of FIG. 14;

FIG. 16 is a plan view illustrating an exemplary embodiment of a second mask process in manufacturing the first substrate of the transistor array substrate, according the present invention;

FIGS. 17A and 17B are cross-sectional views taken along lines XII-XII′ and XIII-XIII′ of FIG. 16;

FIG. 18 is a plan view illustrating an exemplary embodiment of a third mask process in manufacturing the first substrate of the transistor array substrate according the exemplary embodiment of the present invention;

FIGS. 19A and 19B are cross-sectional views taken along lines XIV-XIV′ and XV-XV′ of FIG. 18;

FIG. 20A is a plan view illustrating an exemplary embodiment of a process of attaching the first and second substrates according to the present invention; and

FIG. 20B is plan view illustrating a part ‘A’ shown in FIG. 20A.

### DETAILED DESCRIPTION OF THE INVENTION

The invention will now be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “lower”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “lower” other elements or features would then be oriented “upper” the other elements or features. Thus, the exemplary term “lower” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings.

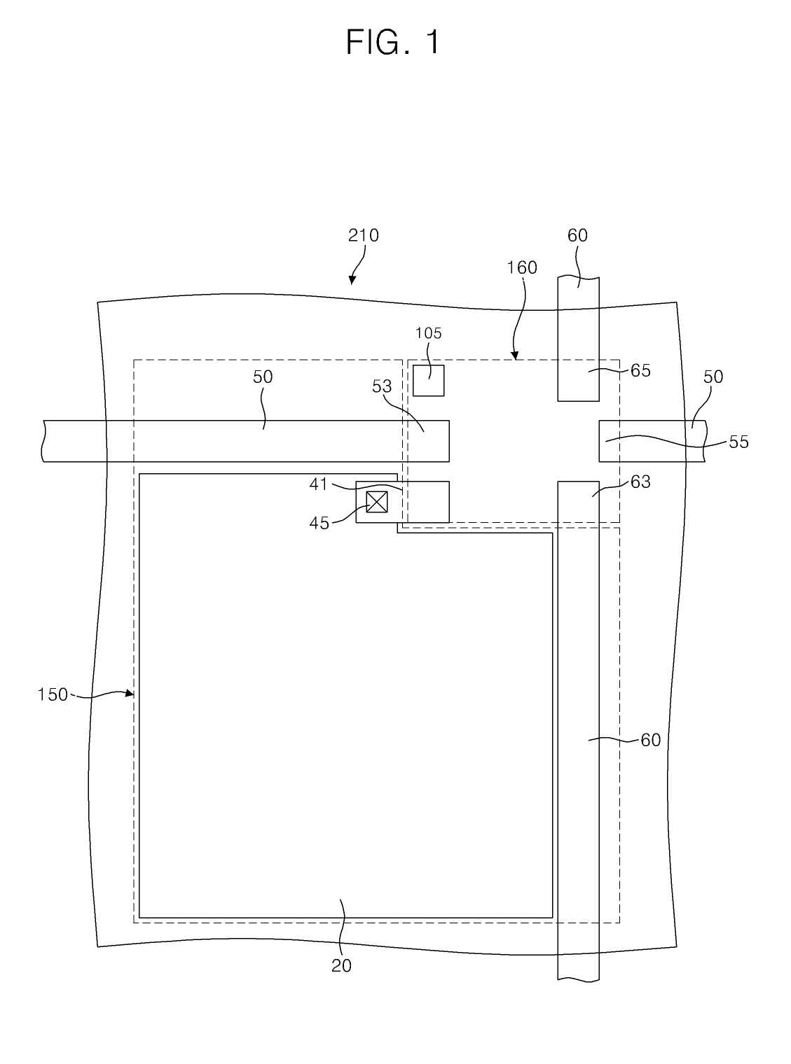

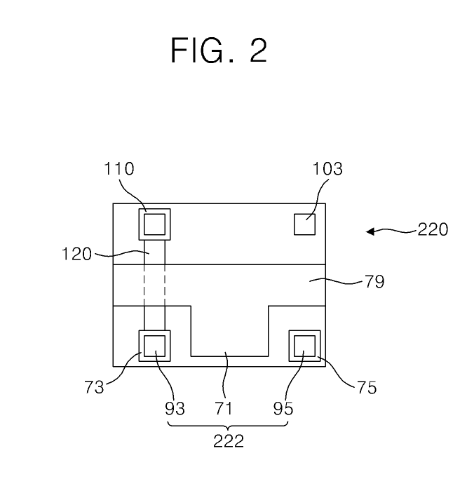

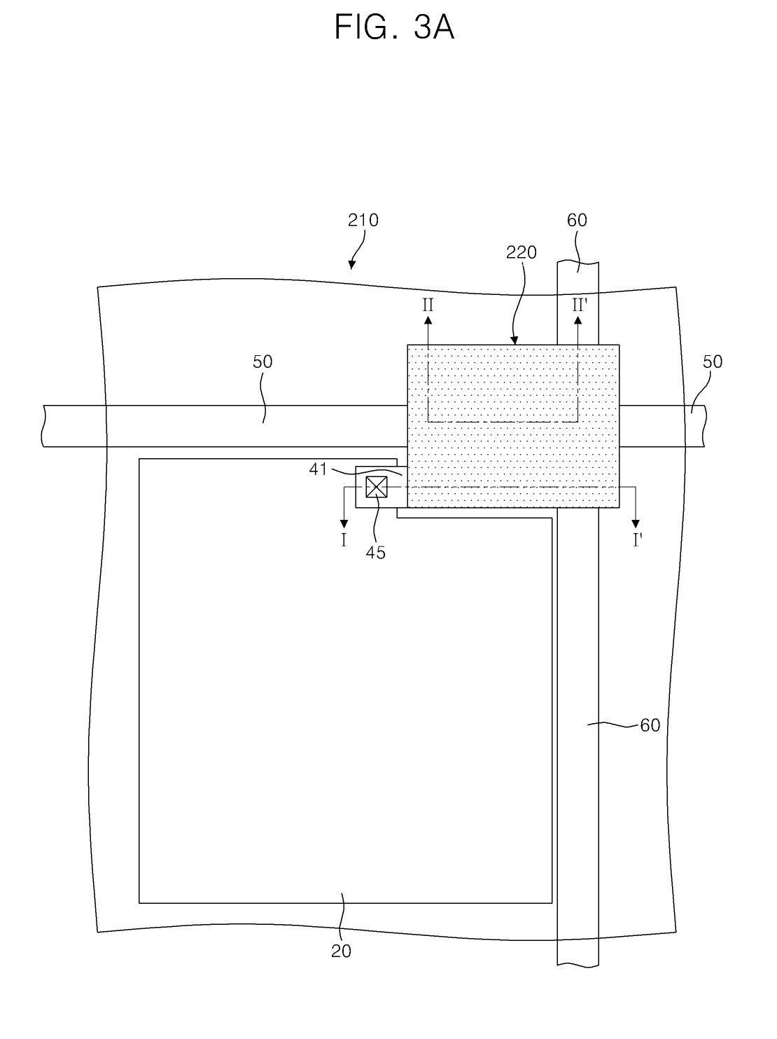

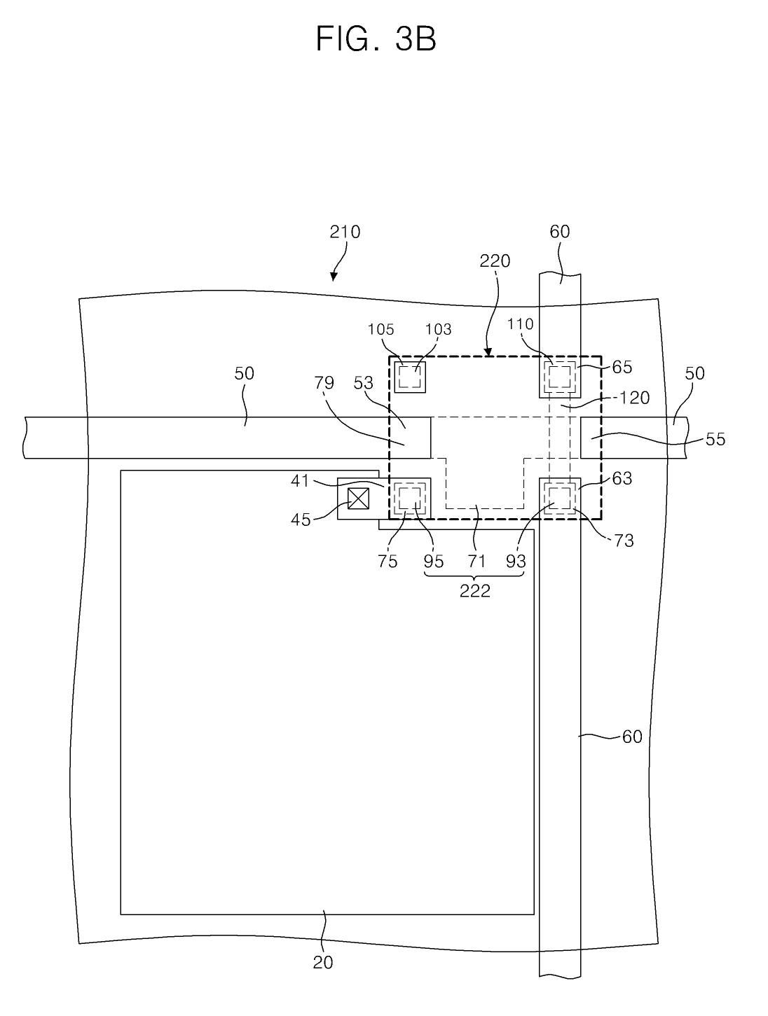

An exemplary embodiment of a transistor array substrate according to the present invention includes a first substrate and a second substrate. The first substrate is shown in FIG. 1, and the second substrate is shown in FIG. 2. The transistor array substrate of the present invention may be manufactured by attaching the first and second substrates to each other as shown in FIGS. 3A and 3B.

FIG. 1 is a plan view illustrating an exemplary embodiment of the first substrate of the transistor array substrate according to the present invention. In particular, FIG. 1 shows one unit pixel of the transistor array substrate. Referring to FIG. 1, the first substrate 210 includes a pixel region 150 and a transistor region 160, as indicated by the dotted outlines of the respective regions.

In the transistor region 160, a second substrate (not shown) with a transistor array is attached to the first substrate 210. In the transistor region 160, connecting portions connected to transistor electrodes, a leveling dummy 105 for adjusting a height, and a portion of a drain electrode 41 connected to a pixel electrode 20 via a contact hole 45, are arranged. As the connecting portions, first and second (adjacent) gate connecting portions 53 and 55, and first and second (adjacent) data connecting portions 63 and 65 are provided.

In the pixel region 150, lines are arranged for transmitting a signal to the transistor region 160, and to the pixel electrode 20 for receiving a data signal voltage. As the lines, a gate line 50 including first disconnected portions extending in a first direction, transmitting a gate driving signal, and a data line 60 including second disconnected portions extending in a second direction substantially perpendicular to the first direction, transmitting a data signal voltage, are provided. The first and second disconnected portions of the gate and data lines 50 and 60, respectively, arranged in the pixel region 150, are connected to the corresponding connecting portions 53 and 55, and 63 and 65 in the transistor region 160, respectively.

As in the illustrated embodiment, the gate and data lines 50 and 60 are formed in a disconnected state in the transistor region 160, and can be electrically connected to gate and data line connecting portions (not shown) arranged in the second substrate.

FIG. 2 is a plan view illustrating an exemplary embodiment of the second substrate of the transistor array substrate according to the present invention. In particular, FIG. 2 shows one unit pixel of the second substrate. The second substrate 220 includes a transistor 222, a data line connecting portion 120, a gate line connecting portion 79, and a leveling dummy 103. In one exemplary embodiment, the transistor 222 is a metal oxide semiconductor (“MOS”) transistor.

The transistor 222 is a switching element for switching a data signal voltage in response to a gate driving signal. The transistor includes a gate electrode 71 extended from the gate line connecting portion 79 (e.g., substantially perpendicularly), a source 93 electrically connected to a source electrode 73, and a drain 95 electrically connected to a drain electrode 75.

The data line connecting portion 120 serves to connect the corresponding connecting portions (see 63 and 65 of FIG. 1) formed in the transistor region 160 of the first substrate 210. The data line connection portion 120 includes one end formed integrally with the source 93 and the other end connected to the connecting portion 110. The gate line connecting portion 79 serves to connect the corresponding connecting portions (see 53 and 55 of FIG. 1) formed in the transistor region 160 of the first substrate 210, and is disposed crossing the data line connecting portion 120, such as in a substantially perpendicular arrangement. The leveling dummy 103 may be used to adjust a height.

FIGS. 3A and 3B are plan views illustrating an exemplary embodiment of the transistor array substrate in which the first substrate of FIG. 1 is coupled with the second substrate of FIG. 2. In FIG. 3B, a coupled portion of the first and second substrates 210 and 220 is seen through, and the second substrate 220 is denoted by a dotted line.

Referring to FIGS. 3A and 3B, the second substrate 220 is coupled in the transistor region 160 of the first substrate 210. In more detail, opposing ends of the gate line connecting portion 79 of the second substrate 220 are connected to the first and second gate connecting portions 53 and 55 of the first substrate 210 to electrically connect the disconnected gate line 50. The gate line connecting portion 70 electrically connects the first disconnected portions of the gate line 50.

The source electrode 73 and the connecting portion 110 connected to the data line connecting portion 120 of the second substrate 220, are connected to the first and second data connecting portions 63 and 65 of the first substrate 210 to electrically connect the disconnected data line 60. The data line connecting portion 120 electrically connects the second disconnected portions of the data line 60.

The drain electrode 75 of the transistor 222 disposed on the second substrate 220, is connected to the drain electrode 41 of the first substrate 210. The leveling dummies 105 and 103 of the first and second substrates 210 and 220 are connected to each other to maintain a height balance, or a distance between the first and the second substrates 210 and 220. In the transistor array substrate of the exemplary embodiment having such a configuration, the transistor 222 is turned on in response to a gate driving signal transmitted to the gate line 50, thereby applying a data signal voltage ultimately transmitted to the data line 60, to the pixel electrode 20.

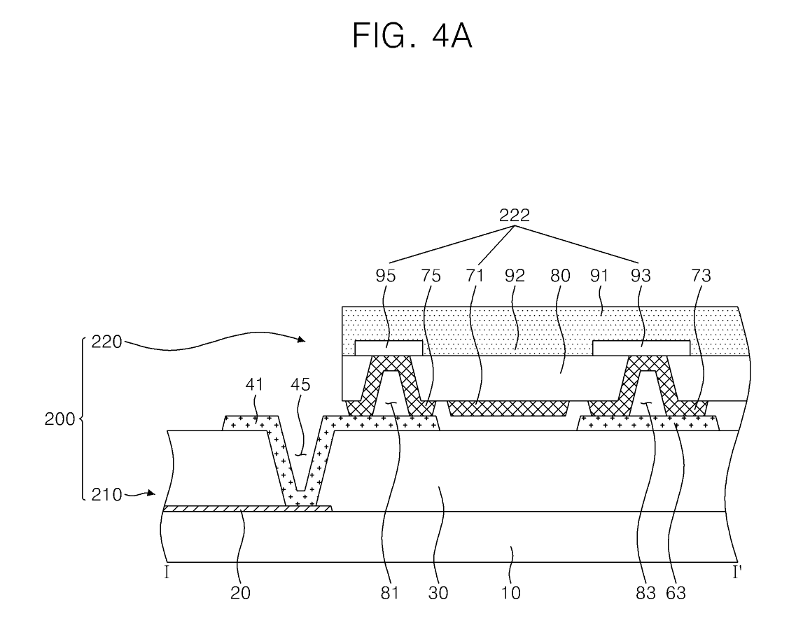

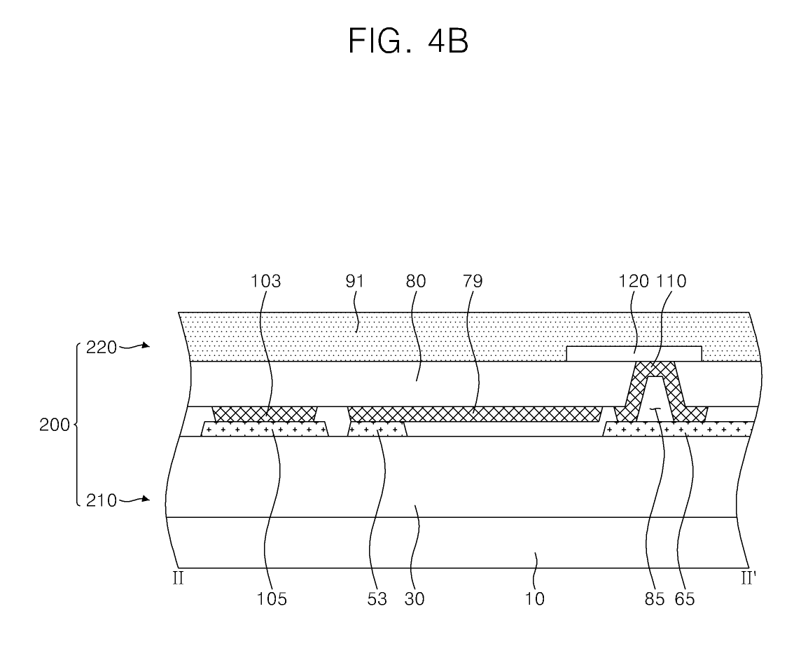

FIGS. 4A and 4B are cross-sectional views illustrating the transistor array substrate taken along lines I-I′ and II-II′ of FIG. 3A. Referring to FIGS. 4A and 4B, in the first (e.g., lower) substrate 210 of the transistor array substrate 200, the pixel electrode 20 is formed on a transparent substrate 10, such as including glass. A passivation film 30 is formed to cover the pixel electrode 20, and includes the contact hole 45 formed therein. The drain electrode 41, the first and second gate connecting portions 53 and 55, the first and second data connecting portions 63 and 65, and the leveling dummy 105 are formed on the passivation film 30. The drain electrode 41 is electrically connected to the pixel electrode 20 via the contact hole 45.

In the second (e.g., upper) substrate 220 of the transistor array substrate 200, an n+ ion is doped into a p-type single crystalline silicon substrate 91, so that the source 93 and the drain 95 are formed therein. A gate oxide layer 80 is formed on the silicon substrate 91, and covers the source 93 and the drain 95. First to third contact holes 81, 83 and 85 are formed in the gate oxide layer 80. The source 93 and the drain 95 are electrically connected to the source and drain electrodes 73 and 75, respectively, via the contact holes 81, 83 and 85, respectively. A channel area 92 is formed between the source 93 and the drain 95 of the silicon substrate 91. The gate electrode 71 is formed on a portion of the gate oxide layer 80 of the second substrate 220 corresponding to the channel area 92. As used herein, “corresponding” may be used to indicate a feature corresponds substantially in shape, dimension or positional placement relative to another feature.

The leveling dummy 103 of the second substrate 220 is arranged on a portion of the gate oxide layer 80 corresponding to the leveling dummy 105 of the first substrate 210. The data connecting portion 120 is disposed in a same level as drain 95 on the second substrate 220, and is connected to the connecting portion 110 formed on the gate oxide layer 80 via the contact hole 85. The gate connecting portion 79 is arranged on a different layer from the data connecting portion 120. As the gate connecting portion 79 is disposed on a different layer from the data connecting portion 120, such as in the gate oxide layer 80, the gate connecting portion 79 is insulated from the data connecting portion 120, by the gate oxide layer 80.

In the illustrated exemplary embodiment, since the transistor 222 in the second substrate 220 may be formed by using crystalline silicon, instead of a TFT manufactured by using amorphous silicon (a-Si), the transistor array substrate 200 has excellent characteristics to thereby improve a response speed of an LCD panel. Advantageously, a size of the LCD panel can be reduced, to thereby improve an aperture ratio.

In the illustrated exemplary embodiment, as a transistor formed in the second substrate 220, an NMOS transistor is formed, but a transistor formed in the second substrate 220 is not limited thereto. In an alternative exemplary embodiment, a PMOS transistor may be formed in the second substrate 220.

The transistor array substrate 200 described in FIGS. 1 to 4B is attached to an opposite substrate (not shown) with a liquid crystal layer interposed therebetween. In an exemplary embodiment, the opposite substrate is a color filter substrate having a common electrode formed therein, and the liquid crystal layer has an anisotropic refractive index and an anisotropic dielectric constant. The transistor 222 of the second substrate 220 is turned on in response to a gate driving signal transmitted from the gate line 50, so that a data driving voltage transmitted from the data line 60 is applied to the pixel electrode 20 through the drain electrode 41.

The liquid crystal layer interposed between the transistor array substrate 200 and the opposite substrate rotates (e.g., aligns) as an electric field is applied to the pixel electrode 20 and the common electrode. The aligning of the liquid crystal layer controls an amount of light passing through the pixel electrode and transmitted toward the opposite substrate.

An exemplary embodiment of a method of manufacturing the transistor array substrate according to the present invention is described below in detail.

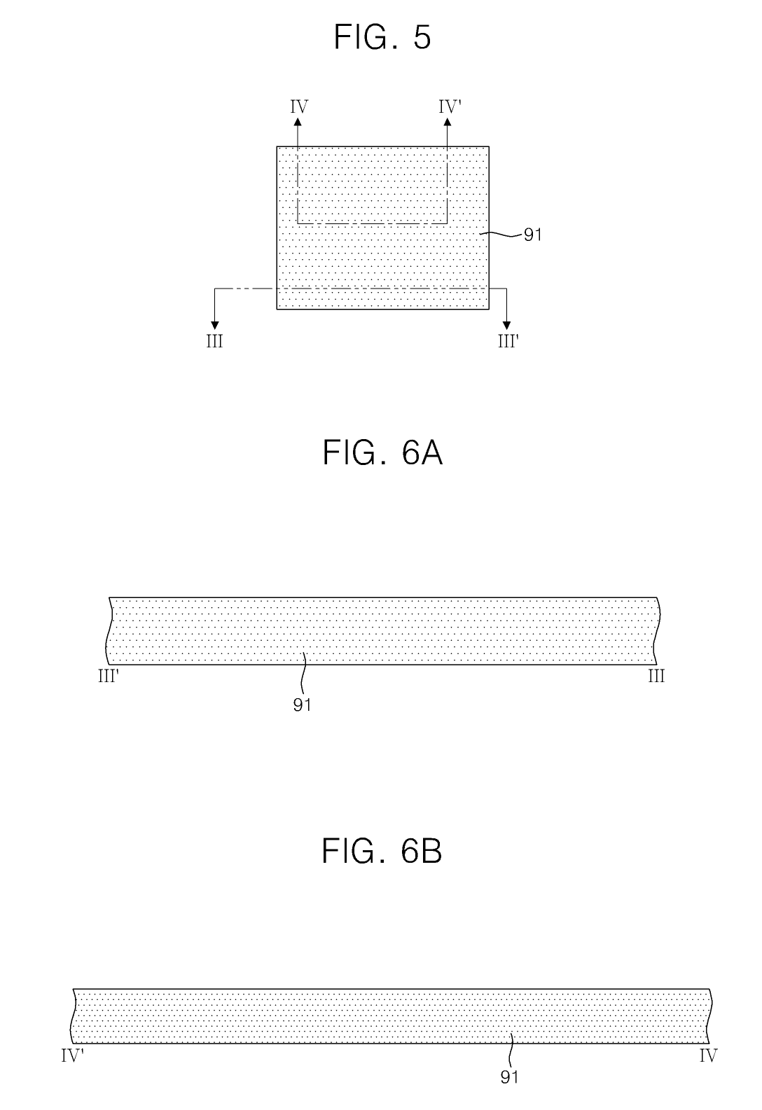

FIG. 5 is a plan view illustrating an exemplary embodiment of a process of preparing a base substrate in manufacturing the second substrate of the transistor array substrate according to the present invention. FIGS. 6A and 6B are cross-sectional views taken along lines III-III′ and IV-IV′ of FIG. 5, respectively.

A base substrate 91 is formed using a p-type single crystalline silicon wafer. In exemplary embodiments, the silicon substrate 91 may be prepared by processing single crystalline silicon made by a Czochralski method, a floating zone method, and any of a number of methods suitable for the purpose described herein.

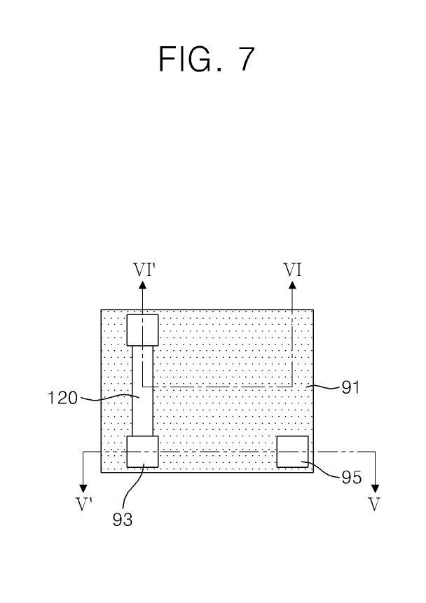

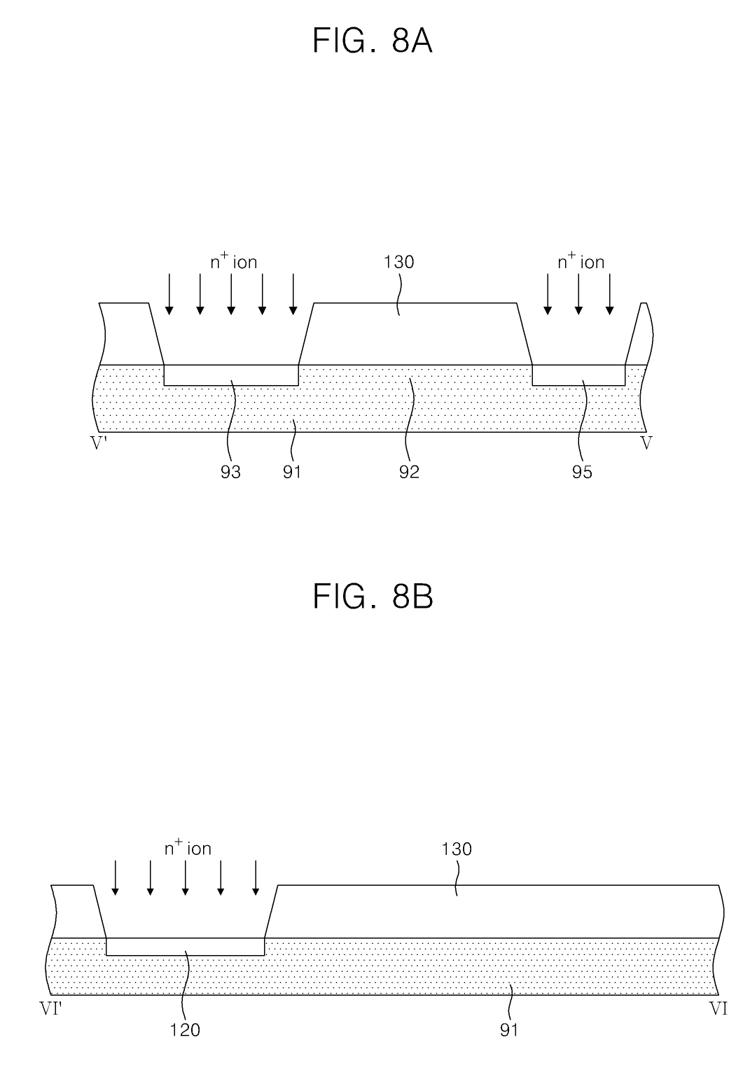

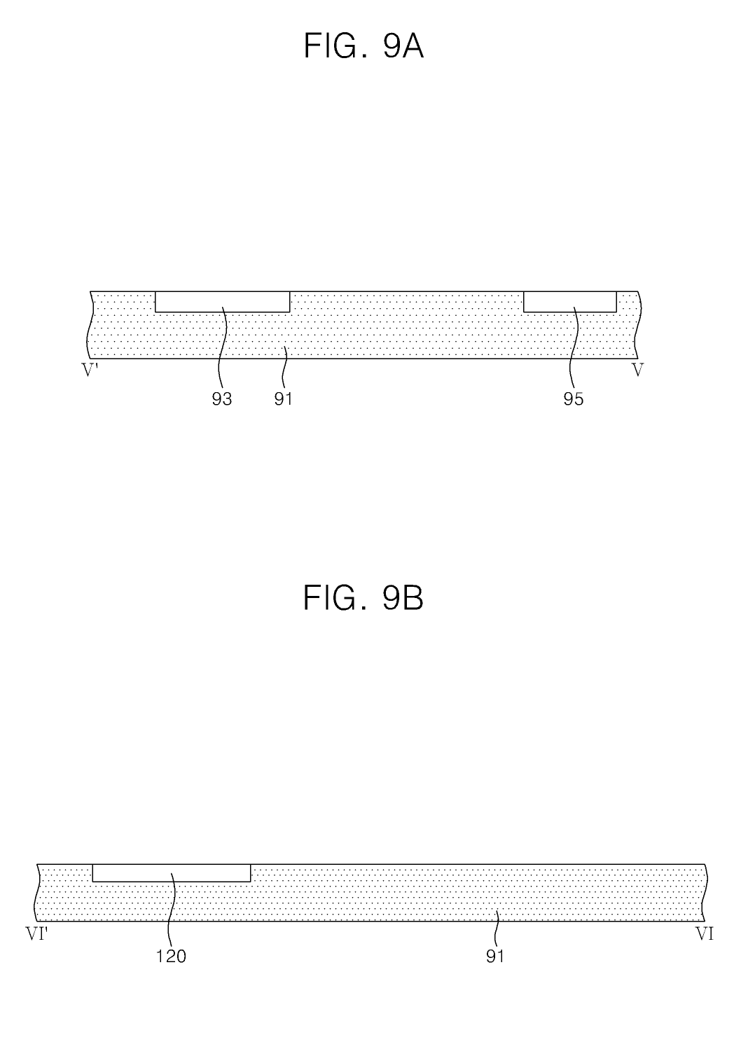

FIG. 7 is a plan view illustrating an exemplary embodiment of a first mask process in the manufacturing of the second substrate of the transistor array substrate according to the present invention. FIGS. 8A and 8B and FIGS. 9A and 9B are cross-sectional views taken along lines V-V′ and VI-VI′ of FIG. 7, respectively. Referring to FIGS. 7, 8A, 8B, 9A, and 9B, an ion is doped into the substrate 91 to form a source 93, a drain 95, and a data connecting portion 120.

A photoresist is coated on the substrate 91. The photoresist may be patterned by a photolithography process using a first mask, thereby forming a photoresist pattern 130. In one exemplary embodiment, the photoresist pattern 130 has a pattern defining regions where the source 93, the drain 95 and the data connecting portion 120 are to be formed.

An n+ ion (indicated by the downward arrows in FIGS. 8A and 8B) is doped into the regions where the source 93, the drain 95 and the data connecting portion 120 are formed, subsequently forming the source 93, the drain 95 and the data connecting portion 120 of the second substrate 220. A predetermined area between the source 93 and the drain 95 becomes a channel area 92. In one exemplary embodiment, the ion doping process may be performed by an ion doping device, such as an ion source, an accelerator, a mass spectrometer, a condenser lens, and/or a deflector. Thereafter, the photoresist pattern 130 is removed, such as using a strip process.

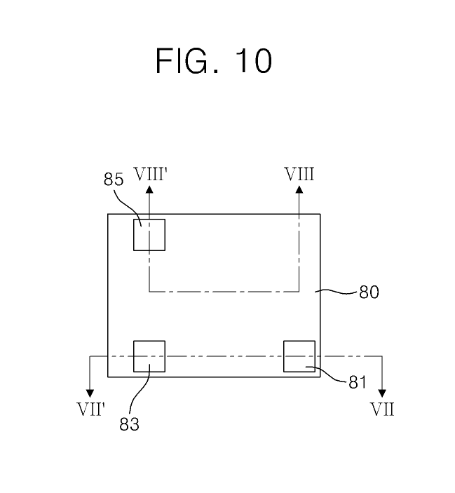

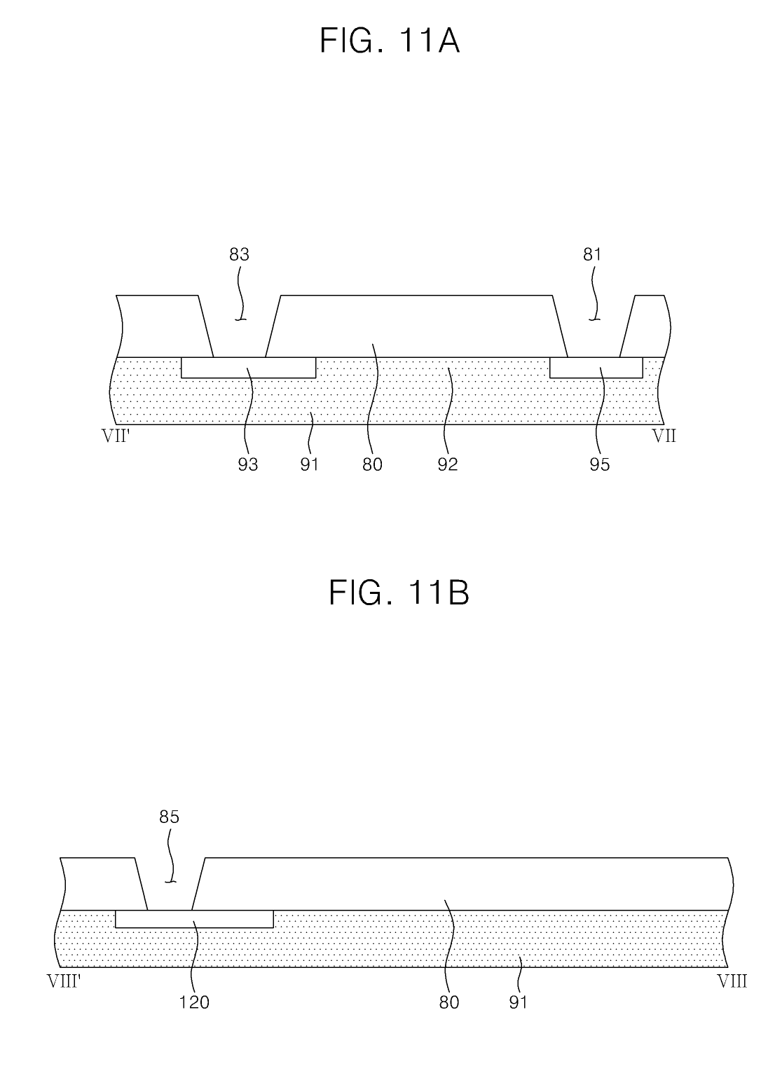

FIG. 10 is a plan view illustrating an exemplary embodiment of a second mask process in the manufacturing of the second substrate of the transistor array substrate according to the present invention. FIGS. 11A and 11B are cross-sectional views taken along lines VII-VII′ and VIII-VIII′ of FIG. 10. Referring to FIGS. 10, 11A and 11B, a gate oxide layer 80 including first to third contact holes 81, 83 and 85 is formed over a whole surface of the substrate 91 having the source 93 and the drain 95 previously formed thereon.

The gate oxide layer 80 is formed over an entire surface of the second substrate 91, such as using a plasma enhanced chemical vapor deposition (“PECVD”) technique. The gate oxide layer 80 may be made of a silicon dioxide (SiO₂). In order to reduce or effectively prevent leakage current between the channel area 92 and the gate electrode (not shown), the gate oxide layer 80 may contain a metal oxide or a metal siligate. For example, the metal oxide may be aluminum oxide or titanium oxide, and the metal siligate may be aluminum silicon oxide or titanium silicon oxide.

The gate oxide layer 80 is patterned, such as by a photoresist process and an etching process, using a second mask. The patterning of the gate oxide layer forms the first contact hole 81 exposing a portion of the drain 95, the second contact hole 83 exposing a portion of the source 93, and the third contact hole 85 exposing a portion of the data connecting portion 120, as illustrated in FIGS. 11A and 11B.

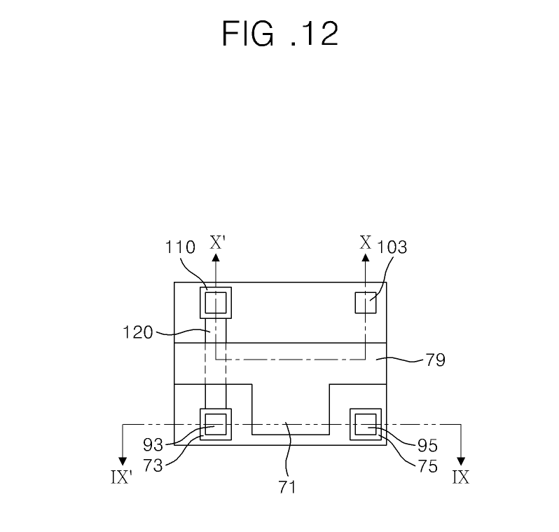

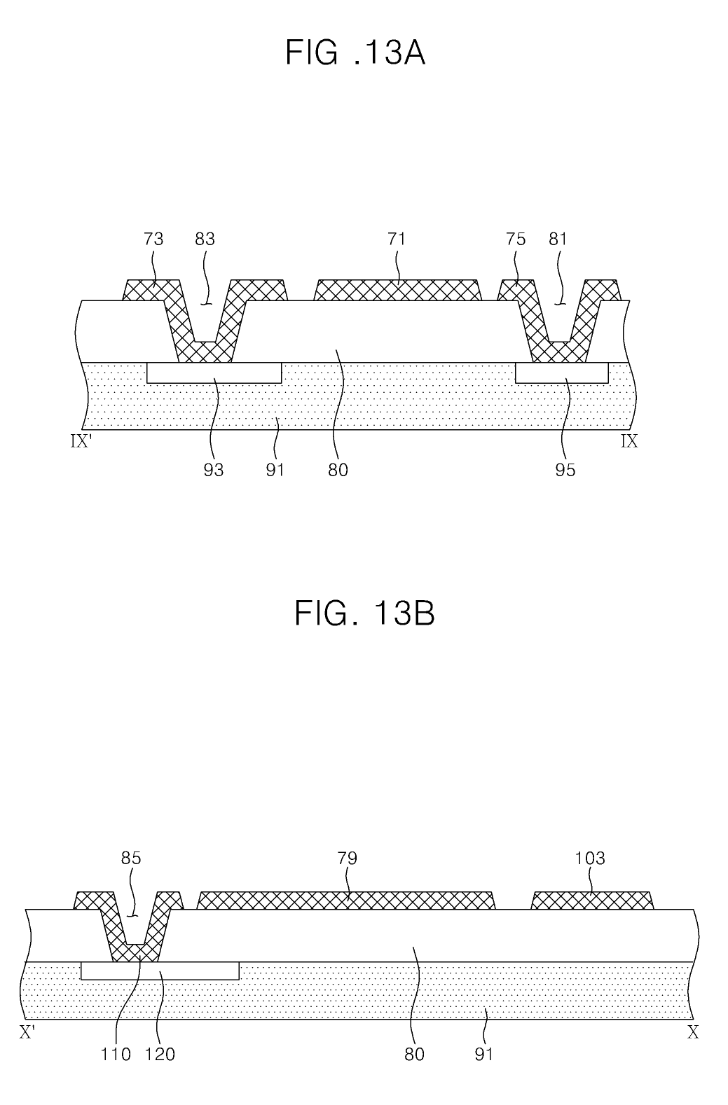

FIG. 12 is a plan view illustrating an exemplary embodiment of a third mask process in the manufacturing of the second substrate of the transistor array substrate according to the present invention. FIGS. 13A and 13B are cross-sectional views taken along lines IX-IX′ and X-X′ of FIG. 12. Referring to FIGS. 12, 13A and 13B, a conductive pattern including a gate connecting portion 79, a gate electrode 71, a second drain electrode 75, a source electrode 73, a connecting portion 110, and a leveling dummy 103 is formed on the gate oxide layer 80 having the first to third contact holes 81, 83 and 85, previously formed therein.

In one exemplary embodiment, the conductive layer may be formed on the gate oxide layer 80, such as by using a PECVD technique or a sputtering technique. The conductive layer may have a single-layer structure or a multi-layer structure made of a metal or metals including, but not limited to, molybdenum (Mo), niobium (Nb), copper (Cu), aluminum (Al), chromium (Cr), silver (Ag), tungsten (W), or their alloy.

In an exemplary embodiment, the conductive layer may contain polycrystalline silicon. Advantageously, the polycrystalline silicon has a low resistance, is relatively stable in a property of matter, is excellent in electric characteristic and can absorb an external stress.

The conductive pattern may be formed by a photoresist process and an etching process using a third mask process. The conductive pattern is a pattern in which the gate connecting portion 79, the gate electrode 71, the second drain electrode 75, the source electrode 73, the connecting portion 110, and the leveling dummy 103 are discriminated. The gate electrode 71, the second drain electrode 75 and the source electrode 73 may be simultaneously formed.

Advantageously, the exemplary embodiment of the manufacturing method using the first to third mask processes described above, can save a mask manufacturing cost because relatively small and low-cost masks can be used, when compared to the conventional method of manufacturing the transistor.

The manufacturing method of the present invention is not limited to using the first to third mask processes as in the illustrated embodiment. For example, a manufacturing method of the second substrate may include a semiconductor manufacturing process.

In the illustrated exemplary embodiment of the present invention, the second substrate including the NMOS transistor using the p-type silicon substrate is manufactured, but the present invention is not limited thereto. For example, the second substrate including the PMOS transistor using n-type silicon substrate may be manufactured.

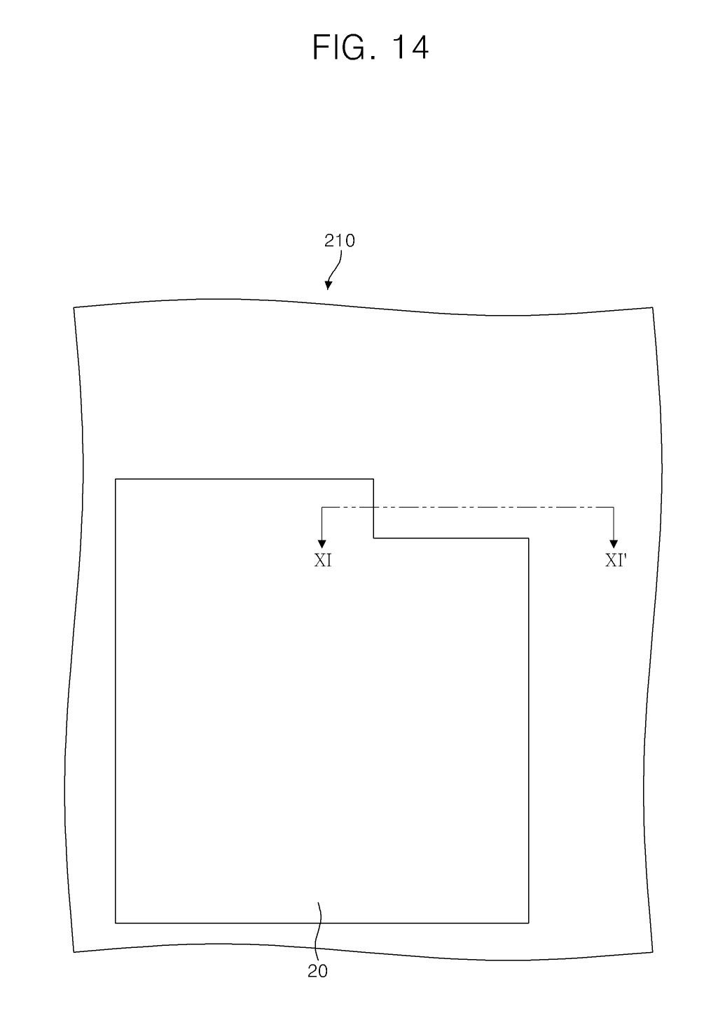

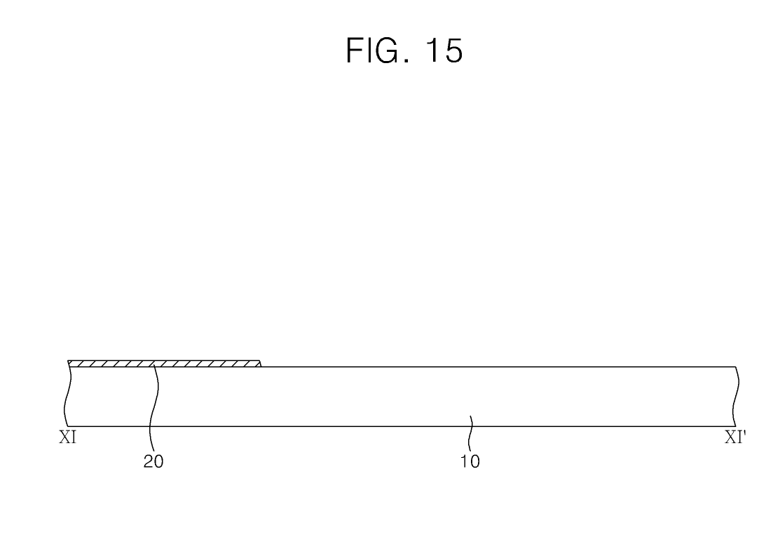

FIG. 14 is a plan view illustrating an exemplary embodiment of a first mask process in manufacturing the first substrate of the transistor array substrate according to the present invention. FIG. 15 is a cross-sectional view taken along line XI-XI′ of FIG. 14. Referring to FIGS. 14 and 15, a pixel electrode 20 is formed on a glass substrate 10.

A transparent conductive layer is formed on the glass substrate 10, such as by using a sputtering technique. The transparent conductive layer may include, but is not limited to, indium tin oxide (ITO), tin oxide (TO), indium zinc oxide (IZO), or indium tin zinc oxide (ITZO). The transparent conductive layer is patterned into the pixel electrode 20, such as by using a photolithography process and an etching process using a first mask.

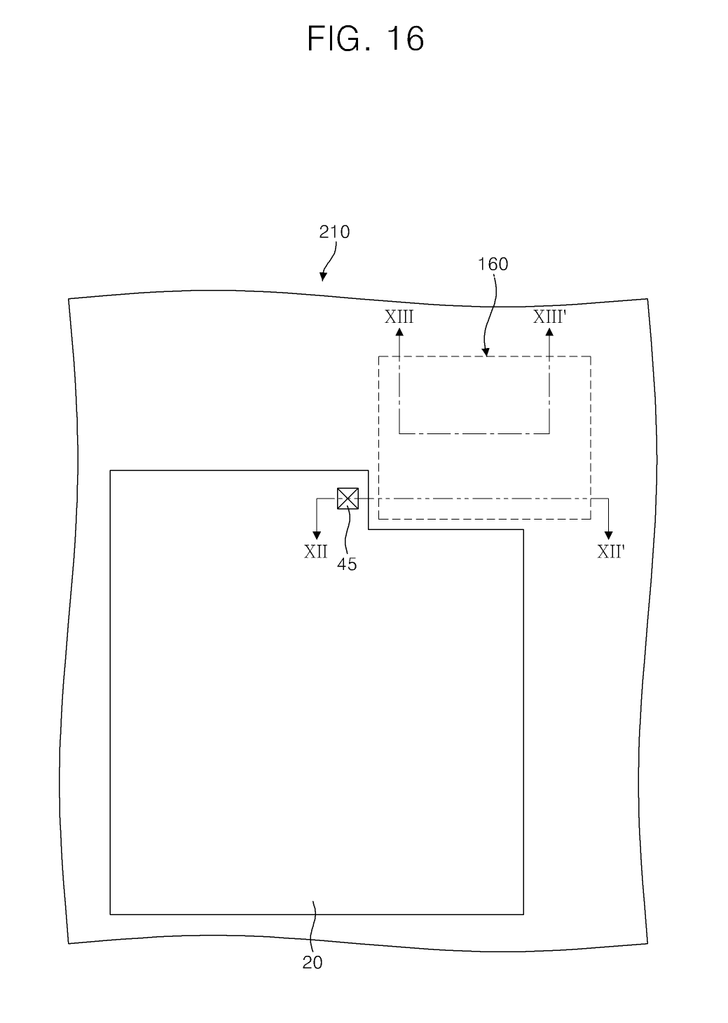

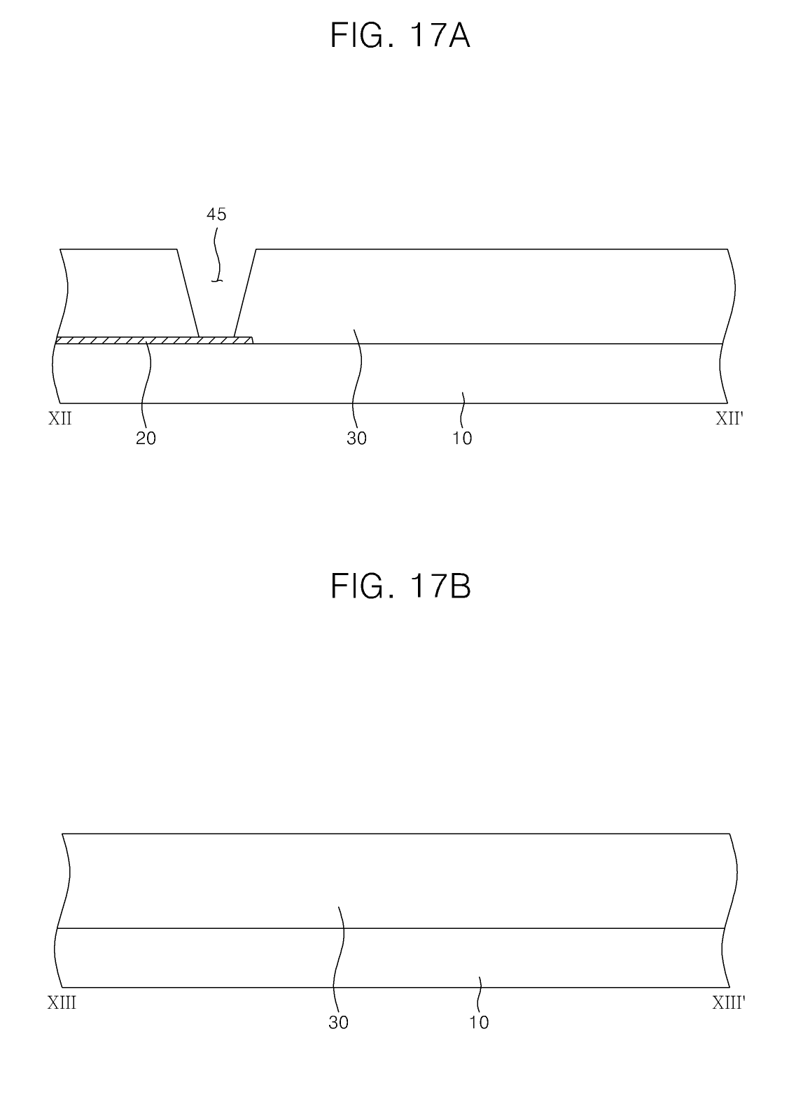

FIG. 16 is a plan view illustrating an exemplary embodiment of a second mask process in the manufacturing the first substrate of the transistor array substrate according the present invention. FIGS. 17A and 17B are cross-sectional views taken along lines XII-XII′ and XIII-XIII′ of FIG. 16. Referring to FIGS. 16, 17A and 17B, a passivation film 30 having a contact hole 45 disposed therein, is formed over a whole surface of the substrate 10 and covering the pixel electrode 20.

The passivation film 30 is formed over the whole surface of the substrate 10 having the pixel electrode 20 already formed thereon, such as by using a PECVD technique. The passivation film 30 may have a single-layer structure or a dual-layer structure made of an organic insulating material or an inorganic insulating material. The passivation film 30 is patterned, such as by using a photoresist process and an etching process using a second mask, thereby forming the contact hole 45 exposing a portion of the pixel electrode 20.

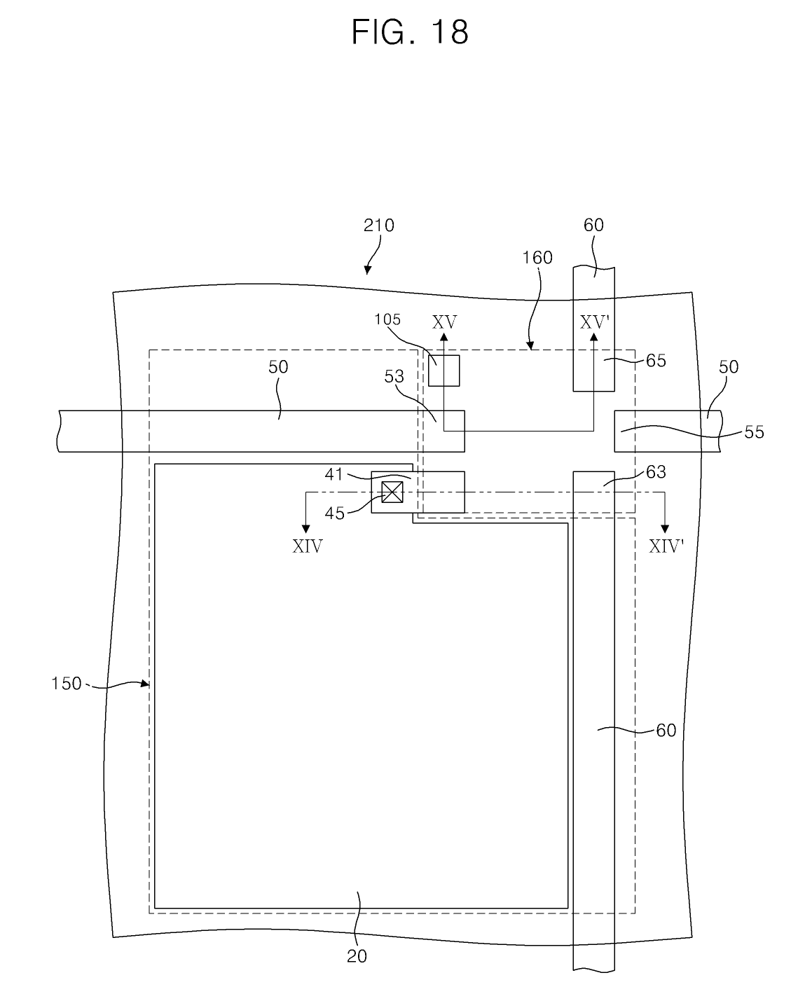

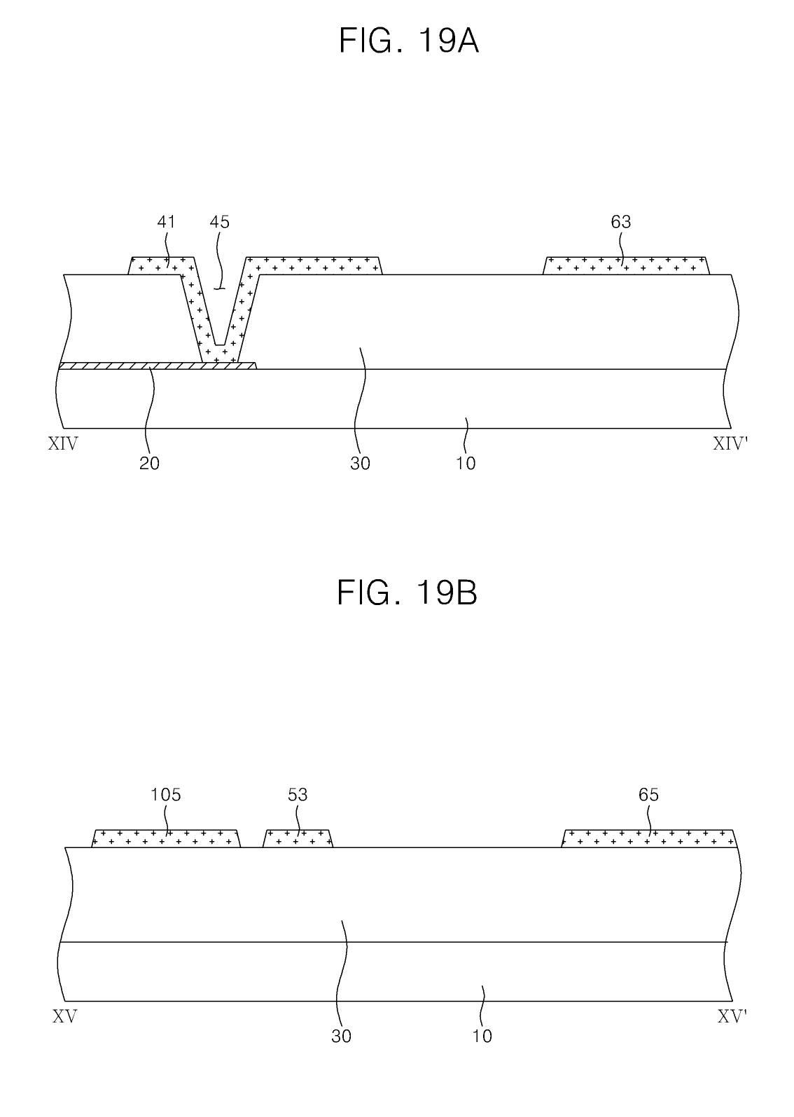

FIG. 18 is a plan view illustrating an exemplary embodiment of a third mask process in the manufacturing of the first substrate of the transistor array substrate according the present invention. FIGS. 19A and 19B are cross-sectional views taken along lines XIV-XIV′ and XV-XV′ of FIG. 18. Referring to FIGS. 18, 19A and 19B, a metal pattern including a drain electrode 41, a gate line 50, a data line 60, a leveling dummy 105, first and second gate connecting portions 53 and 55, and first and second data connecting portions 63 and 65 is formed on the passivation film 30 having the contact hole 45 previously formed therein.

A metal material layer is formed on the passivation film 30 having the contact hole 45. The metal material layer including a single-layer or multi-layer structure, may be formed by a deposition technique, such as a sputtering technique. In an exemplary embodiment, the metal material layer may include, but is not limited to, Mo, Nb, Cu, Al, Cr, Ag, W, or their alloy.

The metal material layer is patterned into a metal pattern including the drain electrode 41, the gate line 50, the data line 60, the leveling dummy 105, the first and second gate connecting portions 53 and 55, and the first and second data connecting portions 63 and 65, such as by using a photoresist process and an etching process using a third mask.

Since the drain electrode 41, the gate line 50, the data line 60, the leveling dummy 105, the first and second gate connecting portions 53 and 55, and the first and second data connecting portions 63 and 65 are formed by a single mask process, the number of mask processes is reduced. Advantageously, the manufacturing process is simplified, and the mask manufacturing cost is consequently reduced.

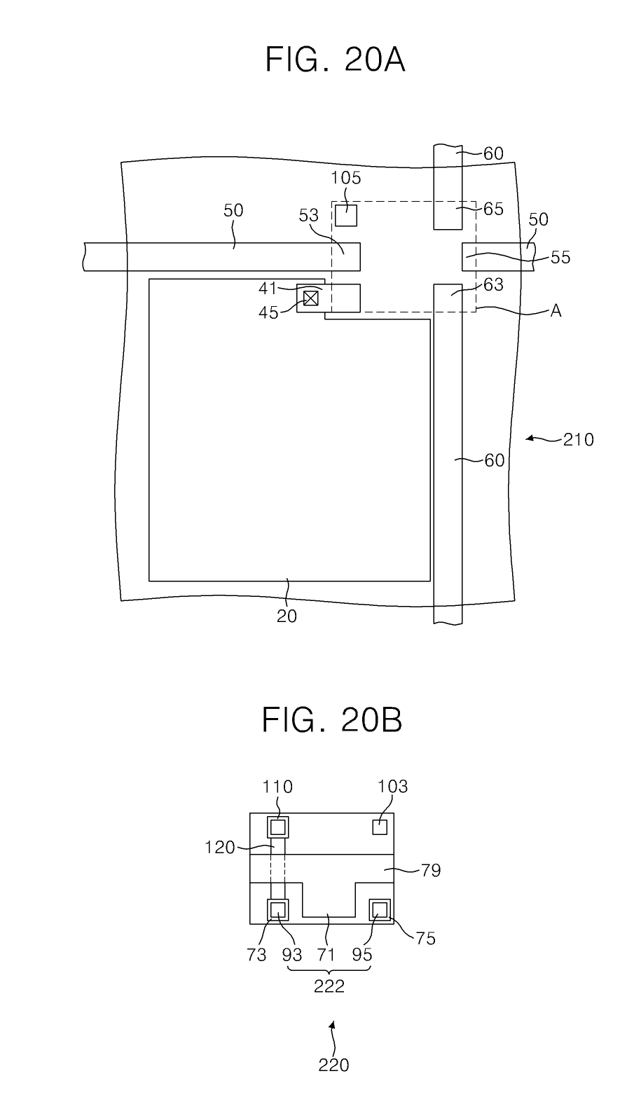

FIG. 20A is a plan view illustrating an exemplary embodiment of a process of attaching the first and second substrates according to the present invention. Referring to FIGS. 20A and 20B, the second substrate 220 is attached to the first substrate 210 in the transistor region 160, in which the disconnected gate line 50 and portions of the data line 60 and the drain electrode 41 are formed. A first face of the second substrate 220 shown in FIG. 20B, and including the gate connection portion 79 and the data connecting portion 120, is disposed to face a first face of the first substrate 210 shown in FIGS. 1 and 20A, and including the first and second disconnected portions of the gate line 50 and data line 60, respectively. In one exemplary embodiment, the second substrate 220 is attached to the first substrate 210 by using a u-contact printing process.

A first end of the gate connecting portion 79 formed in the second substrate 220 is connected to the first gate connecting portion 53 formed in the first substrate 210, and a second end of the gate connecting portion 79 opposing the first end, is connected to the second gate connecting portion 55. The source electrode 73 of the second substrate 220 is connected to the first data connecting portion 63 of the first substrate 210, and the connecting portion 110 of the second substrate 220 is connected to the second data connecting portion 65. The (second) drain electrode 75 of the second substrate 220 is disposed corresponding to and is connected to the (first) drain electrode 41 of the first substrate 210. The leveling dummy 103 of the second substrate 220 is disposed corresponding to and is connected to the leveling dummy 105 of the first substrate 210.

The transistor array substrate 220 of which the gate 71, the source 93 and the drain 95 of the transistor 222 formed on the second substrate 220, are respectively connected to the gate line 50, the pixel electrode 20 and the data line 60 of the first substrate 210, may be manufactured through the processes described in FIGS. 5 to 20 (see FIGS. 3A, 3B, 4A, and 4B).

As in the illustrated embodiments, the transistor array substrate and the method of manufacturing the same according to the present invention has the following advantage. Since a crystalline silicon substrate is used for the transistor array substrate, a characteristic of the transistor, which is a switching element of the LCD device is improved, and since the size of the switching element is reduced, an aperture ratio and light transmissivity are improved. Additionally, since the first substrate is manufactured by the three masks, the mask manufacturing cost is reduced, leading to the simplified manufacturing process. Furthermore, since the size of the mask used to manufacture the second substrate is relatively small, the manufacturing cost is lowered.

As the method of manufacturing the transistor array substrate of the present invention includes a small number of thermal processes, the method can be applied to a flexible display device. Advantageously, since a misalignment may be reduced, or effectively prevented, the method can be applied to a large-scaled flexible display device.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

What is claimed is:

1. A transistor array substrate, comprising:
a first substrate comprising a pixel region and a transistor region,
the pixel region including a pixel electrode, a portion of a disconnected gate line and a portion of a disconnected data line, and
the transistor region including first and second gate connecting portions respectively connected to disconnected portions of the gate line, and first and second data connecting portions respectively connected to disconnected portions of the data line; and
a second substrate comprising:
a gate line connecting portion connected to the first and second gate connecting portions of the first substrate,
a data line connecting portion for connecting the first and second data connecting portions of the first substrate, and
a transistor connected to the gate line connecting portion and the data line connecting portion of the second substrate, and connected to the pixel electrode of the first substrate,
wherein the second substrate is attached to the transistor region of the first substrate.

2. The transistor array substrate of claim 1, wherein the first substrate further comprises:
a passivation film insulating the pixel electrode from the gate line and the data line; and
a first drain electrode disposed overlapping the transistor region, penetrating the passivation film and being connected to the pixel electrode.

3. The transistor array substrate of claim 2, wherein the gate line, the data line and the first drain electrode are disposed on the same layer.

4. The transistor array substrate of claim 3, wherein the second substrate comprises a crystalline silicon substrate.

5. The transistor array substrate of claim 4, wherein the transistor comprises:
a drain including an ion doped into the silicon substrate;
a source including the ion doped into the silicon substrate, the source being connected to the data line connecting portion of the second substrate;
a channel area disposed between the drain and the source of the transistor;
a gate oxide layer disposed covering an entire of the channel area, the source and the drain of the transistor; and
a gate electrode disposed on a portion of the gate oxide layer corresponding to the channel area, the gate electrode being connected to the gate connecting portion.

6. The transistor array substrate of claim 5, wherein the gate oxide layer includes first and second contact holes exposing portions of the drain and the source of the transistor, respectively, and
the second substrate further comprises:
a second drain electrode disposed on the gate oxide layer and connected to the drain of the transistor through the first contact hole, and
a source electrode disposed on the gate oxide layer and connected to the source of the transistor through the second contact hole.

7. The transistor array substrate of claim 6, wherein the data connecting portion is formed integrally with the source.

8. The transistor array substrate of claim 7, wherein the first substrate further comprises a first leveling dummy disposed in the transistor region, and
the second substrate further comprises a second leveling dummy corresponding to the first leveling dummy of the first substrate.

9. A method of manufacturing a transistor array substrate, the method comprising:
manufacturing a first substrate, the first substrate comprising a pixel electrode, a portion of a disconnected gate line and a portion of a disconnected data line;
manufacturing a second substrate, the second substrate comprising a gate line connecting portion, a data line connecting portion and a transistor; and
attaching the second substrate to the first substrate such that the gate line connecting portion connects portions of the disconnected gate line of the first substrate, the data line connecting portion connects portions of the disconnected data line of the first substrate, and the transistor is connected to the pixel electrode of the first substrate.

10. The method of claim 9, wherein the manufacturing a first substrate comprises:
forming the pixel electrode on a glass substrate;
forming a passivation film covering the pixel electrode;
forming a contact hole on the passivation film and exposing a portion of the pixel electrode; and
forming a first pattern including the gate line, the data line and the first drain electrode, the first drain electrode being connected to the pixel electrode through the contact hole on the passivation film.

11. The method of claim 10, wherein the manufacturing a second substrate comprises:
doping an ion into a crystalline silicon substrate and forming a source, a drain and a data line connecting portion formed integrally with the source;
forming an insulating layer on the silicon substrate;
removing the insulating layer and forming first, second and third contact holes exposing portions of the source, the drain and the data line connecting portion of the, respectively; and
forming a second pattern on the insulating layer, the second pattern comprising:
a second drain electrode connected to the drain through the first contact hole,
a source electrode connected to the source through the second contact hole,
a gate electrode formed integrally with the gate connecting portion, and
a connecting portion connected to the drain line connecting portion through the third contact hole.

12. The method of claim 11, wherein the second drain electrode, the source electrode and the gate electrode are simultaneously formed.

13. The method of claim 11, wherein the forming a first pattern comprises:
forming first and second gate connecting portions connected to the portions of the disconnected gate line; and
forming first and second data connecting portions connected to the portions of the disconnected data line.

14. The method of claim 11, wherein forming first, second and third contact holes comprises forming the first and second contact holes exposing portions of the source and the drain, and forming the third contact hole exposing a portion of the data connecting portion.

15. The method of claim 14, wherein the attaching comprises
connecting the second drain electrode to the first drain electrode;
connecting the gate connecting portion to the first and second gate connecting portions; and
connecting the source electrode to the first data connecting portion, and connecting the connecting portion to the second connecting portion.

16. The method of claim 15, wherein the forming a first pattern further comprises forming a first leveling dummy on the first substrate and adjusting a height when the first and second substrates are attached; and
the forming a second pattern further comprises forming a second leveling dummy in the second substrate corresponding to the first leveling dummy.

17. A transistor array substrate, comprising:
a first substrate comprising a pixel electrode, a disconnected gate line and a disconnected data line; and
a second substrate comprising:
a gate line connecting portion connecting the disconnected gate line,
a data line connecting portion connecting the disconnected data line, and
a transistor connected to the gate line connecting portion, the data line connecting portion and the pixel electrode,
wherein the second substrate is attached to the first substrate.

18. The transistor array substrate of claim 17, wherein the second substrate comprises a crystalline silicon substrate.

19. The transistor array substrate of claim 18, wherein the transistor comprises a drain and a source including an ion doped into the crystalline silicon substrate, and a gate electrode insulated from a channel area disposed between the source and the drain.

20. The transistor array substrate of claim 19, wherein the drain is connected to the pixel electrode, the source is connected to the data line connecting portion, and the gate electrode is connected to the gate line connecting portion.

21. The transistor array substrate of claim 20, wherein the data line connecting portion is disposed on the same layer as the drain and the source, and the gate line connecting portion is disposed on the same layer as the gate electrode.

22. The transistor array substrate of claim 21, wherein the first substrate further comprises an insulating layer insulating the pixel electrode from the gate line and the data line.

23. The transistor array substrate of claim 22, wherein the gate line and the data line are disposed on the same layer.
